(19) United States
(12) Patent Application Publication
(10) Pub. No.: US 2025/0040306 A1
(43) Pub. Date: Jan. 30, 2025

(54) DISPLAY DEVICE AND METHOD FOR FABRICATING THE SAME

(71) Applicant: Samsung Display Co., LTD., Yongin-si (KR)

(72) Inventor: Hyun Eok SHIN, Yongin-si (KR)

(73) Assignee: Samsung Display Co., LTD., Yongin-si (KR)

(21) Appl. No.: 18/616,957

(22) Filed: Mar. 26, 2024

(30) Foreign Application Priority Data
Jul. 27, 2023 (KR) 10-2023-0097890

(51) Int. Cl. H01L 33/38; H01L 25/16; H01L 33/42; H01L 33/44

(52) U.S. Cl. CPC H01L 33/385; H01L 25/167; H01L 33/42; H01L 33/44; H01L 2933/0016; H01L 2933/0025

(57) ABSTRACT

A display device includes a substrate having a pixel electrode, a light emitting element disposed on the pixel electrode and including a first semiconductor layer, an active layer, and a second semiconductor layer, a step coverage prevention layer surrounding the light emitting element in a plan view, a common electrode disposed on the light emitting element and the step coverage prevention layer, and an oxidation prevention layer disposed on a portion of the common electrode that does not overlap the light emitting element in a thickness direction. The common electrode includes a first portion disposed on the light emitting element and a second portion disposed between the oxidation prevention layer and the step coverage prevention layer, and a material forming the first portion is an oxide of a material forming the second portion.

### CROSS-REFERENCE TO RELATED APPLICATION(S)

This application claims priority to and benefits of Korean Patent Application No. 10-2023-0097890 under 35 U.S.C. 119, filed on Jul. 27, 2023, in the Korean Intellectual Property Office (KIPO), the entire contents of which are incorporated herein by reference.

### BACKGROUND

### 1. Technical Field

The disclosure relates to a display device and a manufacturing method thereof.

### 2. Description of the Related Art

As the information society develops, demands for display devices for displaying images are increasing in various forms. The display device may be a flat panel display device such as a liquid crystal display, a field emission display, or a light emitting display. The light emitting display device may include an organic light emitting display device including an organic light emitting diode element as a light emitting element, an inorganic light emitting display device including an inorganic semiconductor element as a light emitting element, or a subminiature light emitting diode element (or micro light emitting diode element) as a light emitting element.

Recently, a head mounted display including a light emitting display device has been developed. A head mounted display (HMD) is a glasses-type monitor device of virtual reality (VR) or augmented reality that is worn in the form of glasses or a helmet and focuses on a distance close to the user's eyes.

A high-resolution micro light emitting diode display panel including a micro light emitting diode element is applied to the head-mounted display. To prevent light emitted from the micro light emitting diode element from being mixed with light emitted from another micro light emitting diode elements adjacent thereto, a reflective layer surrounding the micro light emitting diode element may be disposed. However, a mask process and an etching process are required to form the reflective layer surrounding the micro light emitting diode elements.

### BACKGROUND

Aspects and features of embodiments of the disclosure provide a display device capable of blocking and reflecting side light using a common electrode and a manufacturing method thereof.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment, a display device may include a substrate having a pixel electrode, a light emitting element disposed on the pixel electrode and including a first semiconductor layer, an active layer, and a second semiconductor layer, a step coverage prevention layer surrounding the light emitting element in a plan view, a common electrode disposed on the light emitting element and the step coverage prevention layer, and an oxidation prevention layer disposed on a portion of the common electrode that does not overlap the light emitting element in a thickness direction. The common electrode may include a first portion disposed on the light emitting element and a second portion disposed between the oxidation prevention layer and the step coverage prevention layer, and a material forming the first portion may be an oxide of a material forming the second portion.

The first portion may include InSnOₓ and the second portion may include InSn, or the first portion may include InZnOₓ and the second portion may include InZn.

The second portion may extend from the first portion and surround a side surface of the light emitting element.

The second portion may have a sloper structure having a curvature.

The oxidation prevention layer may have the sloper structure having the curvature, and the step coverage prevention layer may have the sloper structure having the curvature.

The second portion, the oxidation prevention layer, and the step coverage prevention layer may have a convex shape on a side surface of the light emitting element.

An upper surface of the second portion may be in contact with the oxidation prevention layer, and a bottom surface of the second portion may be in contact with the step coverage prevention layer.

An amount of In in the second portion may be about 90 wt %.

An upper surface of the second semiconductor layer and the first portion may have a concavo-convex pattern.

The oxidation prevention layer and the step coverage prevention layer may include an insulating material including one of an organic material, an inorganic material, and an organic-inorganic hybrid material.

According to an embodiment, a method of manufacturing a display device may include bonding a first substrate and a second substrate by melting bonding a connection electrode layer disposed between the first substrate having a pixel electrode and the second substrate having a semiconductor material layer, forming a plurality of light emitting elements by removing the second substrate and etching the semiconductor material layer, forming a step coverage prevention layer surrounding the plurality of light emitting elements in a plan view;
depositing a common electrode material layer on the plurality of light emitting elements and the step coverage prevention layer, forming an oxidation prevention layer on a portion of the common electrode material layer that does not overlap the plurality of light emitting elements in a thickness direction, and forming a common electrode by oxidizing a portion of the common electrode material layer disposed on the plurality of light emitting elements.

The common electrode material layer may include In:Sn=90:10 Wt % or In:Zn=90:10 Wt %.

The forming of the step coverage prevention layer may include spreading a material for preventing step coverage on an entire area of the first substrate on which the plurality of light emitting elements is disposed, covering the plurality of light emitting elements with the material for preventing step coverage, and etching the material for preventing step coverage disposed on an upper surface of the plurality of light emitting elements to expose the upper surface of the plurality of light emitting elements after forming a sloper structure having a convex curvature to a side of the plurality of light emitting elements.

The forming of the oxidation prevention layer may include spreading a material for preventing oxidation on the entire area of the first substrate on which the common electrode material layer is deposited, covering the plurality of light emitting elements with the material for preventing oxidation, and etching the material for preventing oxidation disposed on the upper surface of the plurality of light emitting elements to expose the upper surface of the plurality of light emitting elements after forming a sloper structure having a convex curvature to the side of the plurality of light emitting elements.

The oxidation prevention layer and the step coverage prevention layer may include an insulating material including one of an organic material, an inorganic material, and an organic-inorganic hybrid material.

The forming of the common electrode may include oxidizing the common electrode material layer disposed on the upper surface of the plurality of light emitting elements by oxygen plasma treatment.

The plurality of light emitting elements may include a first semiconductor layer, an active layer, and a second semiconductor layer sequentially stacked, and the common electrode may be in contact with an upper surface of the second semiconductor layer.

The second substrate may be a patterned sapphire substrate (PSS) having a concave-convex pattern.

The upper surface of the second semiconductor layer may have the concavo-convex pattern.

A portion of the common electrode formed on an upper surface of the plurality of light emitting elements may have the concave-convex pattern.

According to an embodiment of a display device and a manufacturing method thereof, side light may be reflected only with a common electrode without a side reflective film of a light emitting element, which requires a separate mask process.

However, the effects of the disclosure are not limited to the aforementioned effects, and various other effects are included in the specification.

### BRIEF DESCRIPTION OF THE DRAWINGS

FIG. 1 is a schematic perspective view of a display device according to an embodiment.

FIG. 2 is a plan view of the display panel schematically illustrating area A of FIG. 1.

FIG. 3 is a schematic cross-sectional view of a display panel taken along A-A′ of FIG. 2 according to an embodiment.

FIG. 4 is a schematic cross-sectional view of a display panel taken along B-B′ of FIG. 2 according to an embodiment.

FIG. 5 is a schematic enlarged cross-sectional view of the light emitting element of FIG. 4 according to an embodiment.

FIG. 6 is a schematic enlarged cross-sectional view of the light emitting element of FIG. 4 illustrating a traveling direction of light in a light emitting element according to an embodiment.

FIG. 7 is a graph illustrating transparency according to wavelengths of an upper portion of a common electrode formed according to an embodiment.

FIG. 8 is a schematic cross-sectional view of a display panel taken along B-B′ of FIG. 2 according to an embodiment.

FIG. 9 is a schematic enlarged cross-sectional view of the light emitting element of FIG. 8 according to an embodiment.

FIG. 10 is a schematic enlarged cross-sectional view of the light emitting element of FIG. 8 illustrating a traveling direction of light in a light emitting element according to an embodiment.

FIGS. 11 to 19 are schematic cross-sectional views illustrating a method of manufacturing a display device according to an embodiment.

FIGS. 20 to 28 are schematic cross-sectional views illustrating a method of manufacturing a display device according to another embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments of the disclosure will be described in detail with reference to the accompanying drawings.

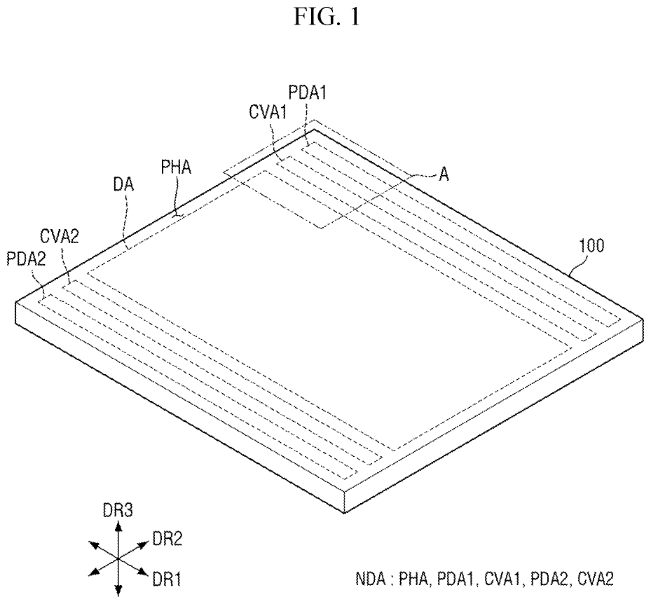

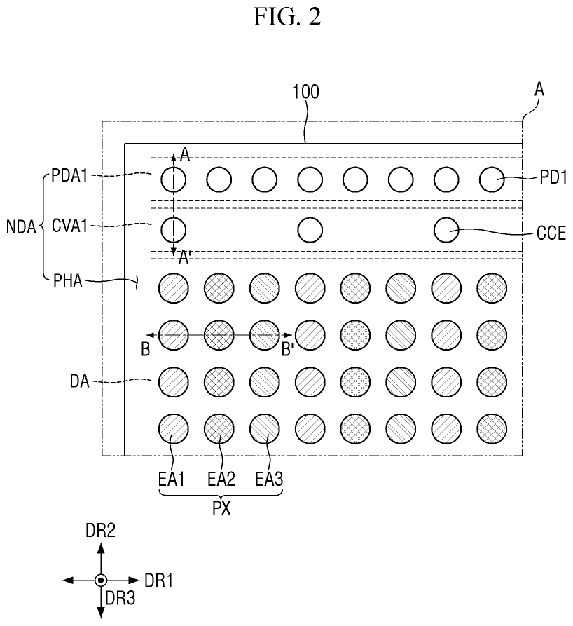

FIG. 1 is a schematic perspective view of a display device according to an embodiment. FIG. 2 is a plan view of the display panel schematically illustrating area A of FIG. 1.

In FIGS. 1 and 2, a display device according to an embodiment has been described as a subminiature light emitting diode display (or micro light emitting diode display) including a subminiature light emitting diode (or micro light emitting diode) as a light emitting element, but the disclosure is not limited thereto.

While FIGS. 1 and 2 describe the display device according to an embodiment as an LEDoS (Light Emitting Diode on Silicon) having light emitting diode elements disposed on a semiconductor circuit board formed using a semiconductor process, it should be noted that the disclosure is not limited thereto.

Furthermore, in FIGS. 1 and 2, a first direction DR1 refers to a horizontal direction of the display panel 100, a second direction DR2 refers to a vertical direction of the display panel 100, and a third direction DR3 refers to a thickness direction of the display panel 100. “Left”, “right”, “top”, and “bottom” refer to directions when the display panel 100 is viewed from a plane (e.g., in a plan view). For example, “right” refers to a side of the first direction DR1, “left” refers to another side of the first direction DR1, “top” refers to a side of the second direction DR2, and “bottom” refers to another side of the second direction DR2. Further, “upper” refers to a first side of the third direction DR3 and “lower” refers to a second side of the third direction DR3.

Referring to FIGS. 1 and 2, a display device according to an embodiment may include a display panel 100 including a display area DA and a non-display area NDA.

The display panel 100 may have a rectangular shape having a long side in the first direction DR1 and a short side in the second direction DR2 in a plan view. However, the planar shape of the display panel 100 is not limited thereto, and the display panel 100 may have a polygonal, circular, elliptical, or atypical planar shape other than a rectangle.

The display area DA may be an area where an image is displayed, and the non-display area NDA may be an area where no image is displayed. The planar shape of the display area DA may follow the planar shape of the display panel 100. In FIG. 1, the planar shape of the display area DA is a rectangle. The display area DA may be disposed in a central area of the display panel 100. The non-display area NDA may be disposed adjacent to the display area DA. The non-display area NDA may be disposed to surround the display area DA in a plan view.

The display area DA of the display panel 100 may include multiple pixels PX. The pixel PX may be a minimum light emitting unit capable of displaying white light.

Each of the pixels PX may include multiple light emitting areas EA1, EA2, and EA3 emitting light. In an embodiment of the disclosure, each of the pixels PX may include three light emitting areas EA1, EA2, and EA3, but the disclosure is not limited thereto. For example, each of the pixels PX may include four emitting areas.

Each of the first light emitting areas EA1 may be an area emitting a first light. Each of the first light emitting areas EA1 may output the first light output from a light emitting element LE as it is. The first light may be light in a blue wavelength band. The blue wavelength band may be in a range of approximately 370 nm to approximately 460 nm, but the disclosure is not limited thereto.

Each of the second light emitting areas EA2 may be an area emitting second light. Each of the second light emitting areas EA2 may convert a portion of the first light emitted from the light emitting element LE into second light and output the second light. The second light may be light in a green wavelength band. The green wavelength band may be in a range of approximately 480 nm to approximately 560 nm, but the disclosure is not limited thereto.

Each of the third light emitting areas EA3 may be an area emitting third light. Each of the third light emitting areas EA2 may convert a portion of the first light emitted from the light emitting element LE into third light and output the third light. The third light may be light in a red wavelength band. The red wavelength band may be in a range of approximately 600 nm to approximately 750 nm, but the disclosure is not limited thereto.

The first light emitting areas EA1, the second light emitting areas EA2, and the third light emitting areas EA3 may be alternately arranged in the first direction DR1. For example, the first light emitting area EA1, the second light emitting area EA2, and the third light emitting area EA3 may be arranged in the order of first light emitting area EA1, second light emitting area EA2, and third light emitting area EA3 in the first direction DR1.

The first light emitting areas EA1 may be arranged in the second direction DR2. The second emitting areas EA2 may be arranged in the second direction DR2. The third light emitting areas EA3 may be arranged in the second direction DR2.

Each of the light emitting areas EA1, EA2, and EA3 may further include at least one of a wavelength conversion layer and a color filter in addition to the light emitting element LE emitting the first light.

The wavelength conversion layer may be disposed on two or more of the first light emitting areas EA1, the second light emitting areas EA2, and the third light emitting areas EA3. For example, wavelength conversion layers may be disposed in the second light emitting areas EA2 and the third light emitting areas EA3. The wavelength conversion layer may include wavelength conversion particles. The wavelength conversion particle may convert light of the blue wavelength band into light of another wavelength, for example, light of a yellow wavelength band. The wavelength conversion particle may be a quantum dot (QD), a quantum rod, a fluorescent material, or a phosphorescent material. The quantum dot may include a group IV nanocrystal, a group II-VI compound nanocrystal, a group III-V compound nanocrystal, a group IV-VI nanocrystal, or a combination thereof.

The quantum dots may include a core and a shell overcoating the core. The core is not limited to this.

The wavelength conversion layer may further include a scatterer for scattering the light of the light emitting element LE in a random direction. The scatterer may include metal oxide particles or organic particles. For example, the metal oxide may be titanium oxide (TiO₂), zirconium oxide (ZrO₂), silicon dioxide (SiO₂), aluminum oxide (Al₂O₃), indium oxide (In₂O₃), zinc oxide (ZnO), or tin oxide (SnO₂). Also, the organic particles may include an acrylic resin or a urethane resin. The scatterers may have a diameter in a range of several to several tens of nanometers.

Multiple color filters may be disposed to overlap multiple pixel circuit units and wavelength conversion layers in a plan view. The color filters may transmit only specific light. For example, the color filters may include first color filters, second color filters, and third color filters. The first color filters may be disposed in the first light emitting area EA1, the second color filters may be disposed in the second light emitting area EA2, and the third color filters may be disposed in the third light emitting area EA3.

Each of the first color filters may transmit the first light and absorb or block the second and third light. For example, each of the first color filters may transmit light in the blue wavelength band and absorb or block light in the green and red wavelength band. Therefore, each of the first color filters may transmit the first light emitted from the light emitting element LE. For example, the first light emitted from the light emitting element LE in the first light emitting area EA1 may be not converted by a separate wavelength conversion layer and may pass through the first color filter. Accordingly, each of the first light emitting areas EA1 may emit the first light.

Each of the second color filters may be disposed on the wavelength conversion layer in the second emitting area EA2. Each of the second color filters may transmit the second light and absorb or block the first and third light. For example, each of the second color filters may transmit light in the green wavelength band and absorb or block light in the blue and red wavelength band. Therefore, each of the second color filters may absorb or block the first light that is not converted by the wavelength conversion layer among the first light emitted from the light emitting element LE. Also, each of the second color filters may transmit the second light corresponding to the green wavelength band among the fourth lights converted by the wavelength conversion layer and absorb or block the third light corresponding to the blue wavelength band. Accordingly, each of the second light emitting areas EA2 may emit the second light.

Each of the third color filters may be disposed on the wavelength conversion layer in the third light emitting area EA3. Each of the third color filters may transmit the third light and absorb or block the first and second light. For example, each of the third color filters may transmit light in the red wavelength band and absorb or block light in the blue and green wavelength band. Therefore, each of the third color filters may absorb or block the first light that is not converted by the wavelength conversion layer among the first light emitted from the light emitting element LE. Also, each of the third color filters may transmit the third light corresponding to the red wavelength band among the fourth lights converted by the wavelength conversion layer and absorb or block the second light corresponding to the green wavelength band. Accordingly, each of the third light emitting areas may emit the third light.

In another embodiment, a light transmitting layer may be formed instead of the wavelength conversion layer of one of the first light emitting area EA1, the second light emitting area EA2, and the third light emitting area EA3. The light transmitting layer may be disposed on a common electrode CE in each of the first light emitting areas EA1. The light transmitting layer may overlap the light emitting element LE in the third direction DR3 in each of the first light emitting areas EA1. The light transmitting layer may include a light transmitting organic material. For example, the light transmitting layer may include an epoxy-based resin, an acrylic-based resin, a cardo-based resin, or an imide-based resin.

In another embodiment, each of the light emitting areas EA1, EA2, and EA3 may include the light emitting element LE that sequentially emits first light, second light, and third light. For example, the first light emitting area EA1 may include a light emitting element LE emitting the first light, the second light emitting area EA2 may include a light emitting element LE emitting the second light, and the third light emitting area EA3 may include a light emitting element LE emitting the third light, and a wavelength conversion layer and/or color filter may be omitted.

The non-display area NDA may include a first common voltage supply area CVA1, a second common voltage supply area CVA2, a first pad unit PDA1, a second pad unit PDA2, and a peripheral area PHA.

The first common voltage supply area CVA1 may be disposed between the first pad unit PDA1 and the display area DA. The second common voltage supply area CVA2 may be disposed between the second pad unit PDA2 and the display area DA. Each of the first common voltage supply area CVA1 and the second common voltage supply area CVA2 may include multiple common connection electrodes CCE connected to the common electrode CE. A common voltage may be supplied to each of the light emitting elements LE1, LE2, and LE3 through the common connection electrodes CCE.

The common connection electrodes CCE of the first common voltage supply area CVA1 may be electrically connected to one of the first pads PD1 of the first pad unit PDA1. For example, the common connection electrodes CCE of the first common voltage supply area CVA1 may receive a common voltage from one of the first pads of the first pad unit PDA1.

The common connection electrodes CCE of the second common voltage supply area CVA2 may be electrically connected to one of the second pads PD2 of the second pad unit PDA2. For example, the common connection electrodes CCE of the second common voltage supply area CVA2 may receive a common voltage from one of the second pads PD2 of the second pad unit PDA2.

The first pad unit PDA1 may be disposed on an upper side of the display panel 100. The first pad unit PDA1 may include first pads PD1 connected to an external circuit board.

The second pad unit PDA2 may be disposed on a bottom side of the display panel 100. The second pad unit PDA2 may include second pads PD2 connected to an external circuit board. In an embodiment, the second pad unit PDA2 may be omitted.

The peripheral area PHA may be an area excluding the first common voltage supply area CVA1, the second common voltage supply area CVA2, the first pad unit PDA1, and the second pad unit PDA2 from the non-display area NDA. The peripheral area PHA may surround the first common voltage supply area CVA1, the second common voltage supply area CVA2, the first pad unit PDA1, and the second pad unit PDA2, as well as the display area DA.

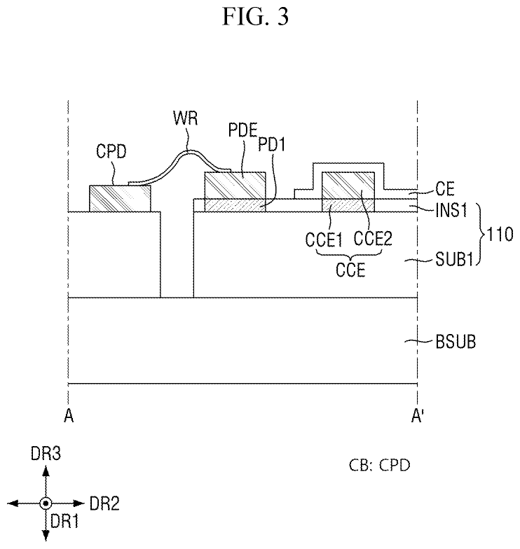

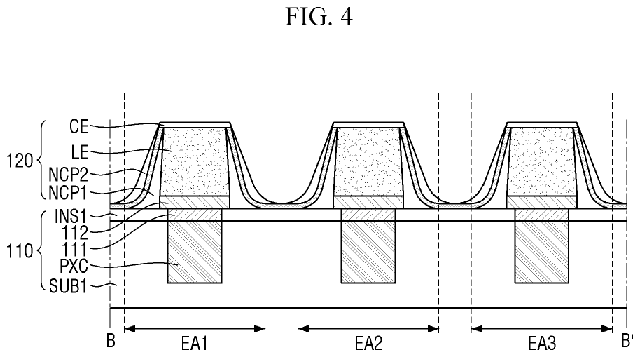

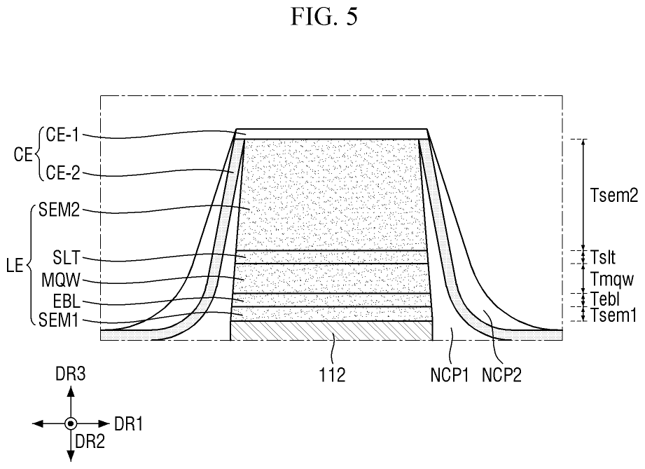

FIG. 3 is a schematic cross-sectional view of a display panel taken along A-A′ of FIG. 2 according to an embodiment. FIG. 4 is a schematic cross-sectional view of a display panel taken along B-B′ of FIG. 2 according to an embodiment. FIG. 5 is a schematic enlarged cross-sectional view of the light emitting element of FIG. 4 according to an embodiment.

Referring to FIGS. 3 to 5, the display panel 100 may include a semiconductor circuit board 110 and a light emitting element layer 120.

The semiconductor circuit board 110 may include a first substrate SUB1, multiple pixel circuit units PXC, pixel electrodes 111, a first pad PD1, and a first common connection electrode CCE1 of the common connection electrode CCE, and a planarization insulating layer INS1.

The first substrate SUB1 may be a silicon wafer substrate. The first substrate SUB1 may be made of single crystal silicon.

Each of the pixel circuit units PXC may be disposed on the first substrate SUB1. Each of the pixel circuit units PXC may include a Complementary Metal-Oxide Semiconductor (CMOS) circuit formed using a semiconductor process. Each of the pixel circuit units PXC may include at least one transistor formed through a semiconductor process. Also, each of the pixel circuit units PXC may further include at least one capacitor formed through a semiconductor process.

The pixel circuit units PXC may be disposed in the display area DA. Each of the pixel circuit units PXC may be connected to a corresponding pixel electrode 111. For example, the pixel circuit units PXC and the pixel electrodes 111 may be connected in a one-to-one correspondence. Each of the pixel circuit units PXC may apply a pixel voltage or an anode voltage to the pixel electrode 111.

Each of the pixel electrodes 111 may be disposed on a corresponding pixel circuit unit PXC. Each of the pixel electrodes 111 may be an exposed electrode exposed from the pixel circuit unit PXC. For example, each of the pixel electrodes 111 may protrude from an upper surface of the pixel circuit unit PXC. Each of the pixel electrodes 111 and the pixel circuit unit PXC may be integral with each other. Each of the pixel electrodes 111 may receive the pixel voltage or the anode voltage from the pixel circuit unit PXC. The pixel electrodes 111 may include aluminum (Al).

Each of the first pad PD1 and the first common connection electrode CCE1 may be an exposed electrode exposed from the first substrate SUB1. The first pad PD1, the first common connection electrode CCE1, and the pixel electrodes 111 may include a same material. For example, the first pad PD1 and the first common connection electrode CCE1 may include aluminum (Al).

Since the second pads of the second pad unit PDA2 may be substantially the same as the first pad PD1 described in conjunction with FIG. 3, a description thereof is omitted.

The planarization insulating layer INS1 may be disposed on the first substrate SUB1 on which the pixel electrodes 111, the first pads PD1, and the first common connection electrode CCE1 are not disposed. The upper surface of the planarization insulating layer INS1, the upper surface of each of the pixel electrodes 111, the upper surface of each of the first pads PD1, and the upper surface of each of the first common connection electrodes CCE1 may continue to be flat (e.g., coplanar with each other). In another embodiment, the planarization insulating layer INS1 may cover the pixel electrodes 111, the first pads PD1, and the first common connection electrode CCE1, and at least a portion of each of the pixel electrodes 111, the first pads PD1, and the first common connection electrode CCE1 may be exposed and not covered by the planarization insulating layer INS1 through contact holes penetrating the planarization insulating layer INS1. The planarization insulating layer INS1 may be formed of an inorganic material such as silicon oxide (SiO₂), aluminum oxide (Al₂O₃), or hafnium oxide (HfOₓ).

The light emitting element layer 120 may include the light emitting areas EA1, EA2, and EA3 and may be a layer emitting light. The light emitting element layer 120 may include connection electrodes 112, a pad connection electrode PDE, a second common connection electrode CCE2 of the common connection electrode CCE, the light emitting elements LE, a step coverage prevention layer NCP1, the common electrode CE, and an oxidation prevention layer NCP2.

Each of the connection electrodes 112 may be disposed on a corresponding pixel electrode 111. For example, the connection electrodes 112 may be connected to the pixel electrodes 111 in a one-to-one correspondence. The connection electrodes 112 may serve as a bonding metal for bonding the pixel electrodes 111 and the light emitting elements LE in a manufacturing process. For example, the connection electrodes 112 may include at least one of gold (Au), copper (Cu), aluminum (Al), and tin (Sn). In an embodiment, the connecting electrodes 112 may include a first layer including one of gold (Au), copper (Cu), aluminum (Al), and tin (Sn) and a second layer including another one of gold (Au), copper (Cu), aluminum (Al), and tin (Sn), and the second layer may be disposed on the first layer.

The pad connection electrode PDE may be disposed on the first pad PD1, and the second common connection electrode CCE2 may be disposed on the first common connection electrode CCE1. The pad connection electrode PDE may contact an upper surface of the first pad PD1, and the second common connection electrode CCE2 may contact an upper surface of the first common connection electrode CCE1. The pad connection electrode PDE, the second common connection electrode CCE2, and the connection electrodes 112 may include a same material. For example, each of the pad connection electrode PDE and the second common connection electrode CCE2 may include at least one of gold (Au), copper (Cu), aluminum (Al), and tin (Sn). In case that each of the connection electrodes 112 includes the first layer and the second layer, each of the pad connection electrode PDE and the second common connection electrode CCE2 may include the first layer and the second layer.

The pad connection electrode PDE may be connected to a pad CPD of the circuit board CB through a conductive connection member such as a wire WR. For example, the first pad PD1, the pad connection electrode PDE, the wire WR, and the pad CPD of the circuit board CB may be electrically connected to each other.

The semiconductor circuit board 110 and the circuit board CB may be disposed on the base substrate BSUB. The semiconductor circuit board 110 and the circuit board CB may be attached to an upper surface of the base substrate BSUB using an adhesive such as a pressure sensitive adhesive.

The circuit board CB may be a flexible printed circuit board (FPCB), a printed circuit board (PCB), a flexible printed circuit (FPC), or a flexible film such as a chip on film (COF).

Each of the light emitting elements LE may be disposed on the connection electrode 112. The light emitting element LE may be a vertical light emitting diode element extending in the third direction DR3. For example, the length of the light emitting element LE in the third direction DR3 may be greater than the length of the light emitting element LE in the horizontal direction. The length in the horizontal direction be the length in the first direction DR1 or the length in the second direction DR2. For example, the length of the light emitting element LE in the third direction DR3 may be in a range of approximately 1 μm to approximately 5 μm.

The light emitting element LE may be a micro light emitting diode element or a nano light emitting diode element. The light emitting element LE may include a first semiconductor layer SEM1, an electron blocking layer EBL, an active layer MQW, a superlattice layer SLT, and a second semiconductor layer SEM2 stacked in the third direction DR3 as shown in FIG. 5. The first semiconductor layer SEM1, the electron blocking layer EBL, the active layer MQW, the superlattice layer SLT, and the second semiconductor layer SEM2 may be sequentially stacked in the third direction DR3.

The first semiconductor layer SEM1 may be disposed on the connection electrode 112. The first semiconductor layer SEM1 may be doped with a first conductivity type dopant such as Mg, Zn, Ca, Se, or Ba. For example, the first semiconductor layer SEM1 may be p-GaN doped with p-type Mg. The thickness Tsem1 of the first semiconductor layer SEM1 may be in a range of approximately 30 to approximately 200 nm.

The electron blocking layer EBL may be disposed on the first semiconductor layer SEM1. The electron blocking layer EBL may be a layer for suppressing or preventing too many electrons from flowing into the active layer MQW. For example, the electron blocking layer EBL may be p-AlGaN doped with p-type Mg. A thickness Teb1 of the electron blocking layer EBL may be in a range of approximately 10 nm to approximately 50 nm. In an embodiment, the electron blocking layer EBL may be omitted.

The active layer MQW may be disposed on the electron blocking layer EBL. The active layer MQW may emit light by combining electron-hole pairs according to electrical signals applied through the first semiconductor layer SEM1 and the second semiconductor layer SEM2. The active layer MQW may emit first light having a central wavelength in a range of approximately 450 nm to approximately 495 nm, for example, light in the blue wavelength band, but the disclosure is not limited thereto.

The active layer MQW may include a material having a single or multi-quantum well structure. In case that the active layer MQW includes a material having a multi-quantum well structure, the active layer MQW may have a structure in which multiple well layers and barrier layers are alternately stacked each other. The well layer may be formed of InGaN, and the barrier layer may be formed of GaN or AlGaN, but the disclosure is not limited thereto. The thickness of the well layer may be in a range of approximately 1 to approximately 4 nm, and the thickness of the barrier layer may be in a range of approximately 3 to approximately 10 nm.

In another embodiment, the active layer MQW may have a structure in which semiconductor materials having a high band gap energy and semiconductor materials having a low band gap energy are alternately stacked with each other, and may include Group 3 to 5 semiconductor materials according to the wavelength range of emitted light. The light emitted from the active layer MQW is not limited to the first light (light in the blue wavelength band) and may emit second light (light in the green wavelength band) or third light (light in the red wavelength band) in embodiments.

The superlattice layer SLT may be disposed on the active layer MQW. The superlattice layer SLT may be a layer for relieving stress between the second semiconductor layer SEM2 and the active layer MQW. For example, the superlattice layer SLT may be formed of InGaN or GaN. A thickness Tslt of the superlattice layer SLT may be in a range of approximately 50 to approximately 200 nm. In an embodiment, the superlattice layer SLT may be omitted.

The second semiconductor layer SEM2 may be disposed on the superlattice layer SLT. The second semiconductor layer SEM2 may be doped with a second conductivity type dopant such as Si, Ge, or Sn. For example, the second semiconductor layer SEM2 may be n-GaN doped with n-type Si. A thickness Tsem2 of the second semiconductor layer SEM2 may be in a range of approximately 500 nm to approximately 1 μm.

The upper surface of the second semiconductor layer SEM2 may contact (e.g., directly contact) a common electrode CE, which will be described below.

The common electrode CE may be disposed on an upper surface of each light emitting element LE and an upper surface of the step coverage prevention layer NCP1 on which the light emitting element LE is not disposed. The common electrode CE may be disposed on the entire surface of the pixels. The common electrode CE may completely cover each of the light emitting elements LE.

The common electrode CE may include a first portion CE-1 disposed on the upper surface of each of the light emitting elements LE and a second portion CE-2 disposed on the upper surface of the planarization insulating layer INS1 that does not overlap the light emitting element LE. The first portion CE-1 and the second portion CE-2 may be integral with each other. The second portion CE-2 may extend from the first portion CE-1 and may be integrally formed.

The first portion CE-1 may include a transparent conductive oxide. The first portion CE-1 may include an oxide of a material constituting the second portion CE-2. For example, the first portion CE-1 may include InSnOₓ or InZnOₓ.

The second portion CE-2 may extend from the first portion CE-1 toward the planarization insulating layer INS1 on which the light emitting element LE is not disposed. The second portion CE-2 may surround the side surface of the light emitting element LE. The second portion CE-2 may have a sloper structure having a curvature. The second portion CE-2 may have a convex shape toward the side of the light emitting element LE.

The second portion CE-2 may include a conductive material having relatively high reflectivity. The second portion CE-2 and the first portion CE-1 may include a same material. For example, in case that the first portion CE-1 includes InSnOₓ, the second portion CE-2 may include InSn. The second portion CE-2 may be made of a material of In:Sn=90:10 wt %. In case that the first portion CE-1 includes InZnOₓ, the second portion CE-2 may include InZn. The second portion CE-2 may be made of a material of In:Zn=90:10 wt %.

The first portion CE-1 may include a material formed by oxidizing a material included in the second portion CE-2. The first portion CE-1 may have higher transparency than the second portion CE-2, and the second portion CE-2 may have higher reflectivity than the first portion CE-1.

The step coverage prevention layer NCP1 may be disposed between the second portion CE-2 and the light emitting element LE.

A step coverage refers to a covering state of the film at the step portion on the surface of the semiconductor element thin film, and the step coverage may affect (e.g., directly affect) the disconnection defect of the wiring and cause deterioration in quality.

For example, in case that the common electrode CE is formed along the upper and side surfaces of the light emitting element LE, a step difference may occur at a corner portion of the upper surface of the light emitting element LE. Therefore, the step coverage prevention layer NCP1 may be disposed on the side of the light emitting element LE to form the common electrode CE extending from the upper surface to the side surface of the light emitting element LE smoothly to prevent the above-described step coverage.

The step coverage prevention layer NCP1 may surround the side surface of the light emitting element LE. The step coverage prevention layer NCP1 may have a convex shape toward the side of the light emitting element LE. The step coverage prevention layer NCP1 may contact (e.g., directly contact) the side surface of the light emitting element LE. Also, the step coverage prevention layer NCP1 may contact (e.g., directly contact) the second portion CE-2 of the common electrode CE.

The step coverage prevention layer NCP1 may have a sloper structure having a curvature formed in downward diagonal direction from a corner where the upper and side surfaces of the light emitting element LE meet.

Accordingly, the second portion CE-2 disposed on the step coverage prevention layer NCP1 may be also formed as a sloper structure having a curvature. In this way, the common electrode CE may be stably supported, and the occurrence of a step difference may be prevented.

The step coverage prevention layer NCP1 may be formed of one of an organic material, an inorganic material, or an organic-inorganic hybrid material.

The inorganic material may include, for example, silicon oxide (SiO₂), aluminum oxide (Al₂O₃), or hafnium oxide (HfOₓ). The organic material may include an epoxy-based resin, an acrylic-based resin, a cardo-based resin, or an imide-based resin. The organic-inorganic hybrid material may be a material that has the properties of organic materials and inorganic materials by physically or chemically combining organic and inorganic materials.

For example, the organic-inorganic hybrid materials may be prepared by the sol-gel method, the low-temperature method, the melting intercalation method, and the self-assembly method of manufacturing an organic-inorganic composite thin film using electrostatic force.

The oxidation prevention layer NCP2 may be disposed on the common electrode CE that does not overlap the upper surface of the light emitting element LE in the third direction DR3.

The oxidation prevention layer NCP2 may surround the side surface of the light emitting element LE. The oxidation prevention layer NCP2 may have a convex shape toward the side of the light emitting element LE. The oxidation prevention layer NCP2 may contact (e.g., directly contact) the upper surface of the second portion CE-2 of the common electrode CE.

The oxidation prevention layer NCP2 may have a sloper structure having a curvature formed in the downward diagonal direction from the corner where the first portion CE-1 and the second portion CE-2 of the common electrode CE meet.

The oxidation prevention layer NCP2 may be formed of one of an organic material, an inorganic material, or an organic-inorganic hybrid material.

The inorganic material may include, for example, silicon oxide (SiO₂), aluminum oxide (Al₂O₃), or hafnium oxide (HfOₓ). The organic material may include an epoxy-based resin, an acrylic-based resin, a cardo-based resin, or an imide-based resin. The organic-inorganic hybrid material may be a material that has the properties of organic materials and inorganic materials by physically or chemically combining organic and inorganic materials.

The non-display area NDA may include a first common voltage supply area CVA1, a second common voltage supply area CVA2, the first pad unit PDA1, and the second pad unit PDA2.

The first common voltage supply area CVA1 may be disposed between the first pad unit PDA1 and the display area DA. The second common voltage supply area CVA2 may be disposed between the second pad unit PDA2 and the display area DA. Each of the first common voltage supply area CVA1 and the second common voltage supply area CVA2 may include multiple common connection electrodes CCE connected to the common electrode (CE of FIGS. 3 and 4). As a result, the common voltage may be supplied to the common electrode (CE of FIGS. 3 and 4) through the common connection electrodes CCE. The common connection electrodes CCE of the first common voltage supply area CVA1 may be electrically connected to one of the first pads PD1 of the first pad unit PDA1. The common connection electrodes CCE of the second common voltage supply area CVA2 may be electrically connected to one of the second pads PD2 of the second pad unit PDA2.

The first pad unit PDA1 may be disposed adjacent to the top side of the display panel 100. The first pad unit PDA1 may include first pads PD1 connected to an external circuit board (CB in FIG. 3).

The second pad unit PDA2 may be disposed adjacent to the bottom side of the display panel 100. The second pad unit PDA2 may include second pads connected to the external circuit board (CB in FIG. 3). In an embodiment, the second pad unit PDA2 may be omitted.

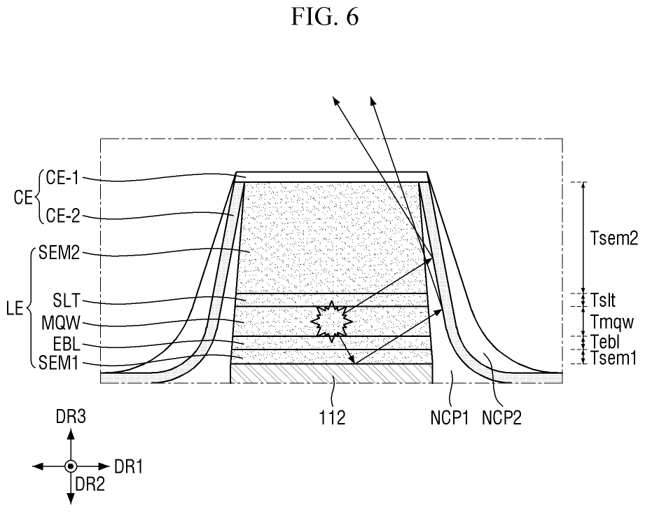

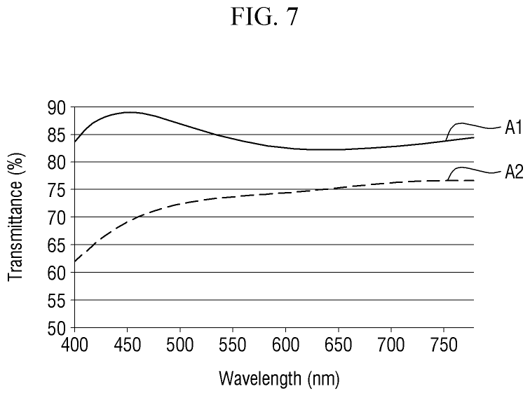

FIG. 6 is a schematic enlarged cross-sectional view of the light emitting element of FIG. 4 illustrating a traveling direction of light in a light emitting element according to an embodiment. FIG. 7 is a graph illustrating transparency according to wavelengths of an upper portion of a common electrode formed according to an embodiment.

As shown in FIG. 6, the common electrode CE may include the first portion CE-1 disposed above the light emitting element LE and the second portion CE-2 surrounding the side surface of the light emitting element LE.

The first portion CE-1 and the second portion CE-2 may be integrally formed, but the first portion CE-1 may be made of an oxide of a material constituting the second portion CE-2. For example, the first portion CE-1 may be made of InSnOₓ, and the second portion CE-2 may be made of InSn (In:Sn=90:10 Wt %). In another example, the first portion CE-1 may be made of InZnOₓ, and the second portion CE-2 may be made of InZn (In:Zn=90:10 Wt %).

Accordingly, the first portion CE-1 and the second portion CE-2 may have different physical properties. The first portion CE-1 may have higher transmittance than the second portion CE-2, and the second portion CE-2 may have higher reflectivity than the first portion CE-1.

Accordingly, the light emitted from the active layer MQW to the side of the light emitting element LE may be reflected by the second portion CE-2 of the common electrode CE and proceed to the upper surface of the light emitting element LE. The light transmitting to the upper surface of the light emitting element LE may pass through the first portion CE-1 with little loss.

Referring to FIG. 7, in case that the first portion CE-1 of the common electrode CE according to an embodiment is formed of InSnOₓ and a thickness of 1250 Å, the transmittance according to wavelength is shown. In the graph of FIG. 7, A1, shown as a solid line, indicates the permeability of the first portion CE-1 in an oxygen atmosphere, and A2, shown as a dashed line, indicates the permeability of the first portion CE-1 in an oxygen-deficient condition.

It can be seen that the transmittance of the first portion CE-1 in the oxygen atmosphere is similar to the transmittance of the conventional common electrode. For example, it can be seen that the transmittance of the first portion CE-1 is about 84% at a wavelength of 550 nm.

In case that the first portion CE-1 of the common electrode CE is formed with InSnOₓ and a thickness of 1250 Å, the sheet resistance is about 22.0Ω and the resistivity is about 275 μΩ-cm, which is equivalent to the sheet resistance of the conventional common electrode.

Here, the conventional common electrode refers to ITO (Indium Tin Oxide; InSnOx) or IZO (Indium Zinc Oxide; InZnOx).

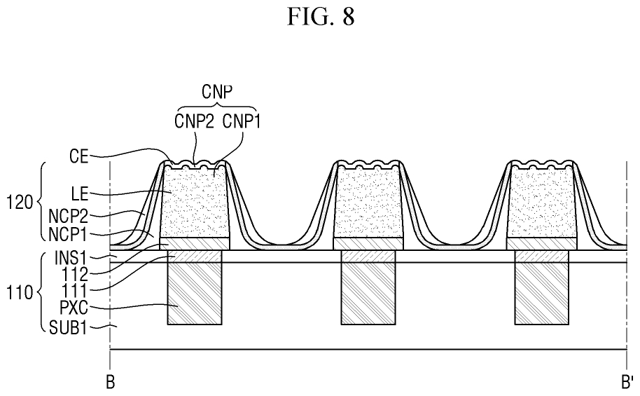

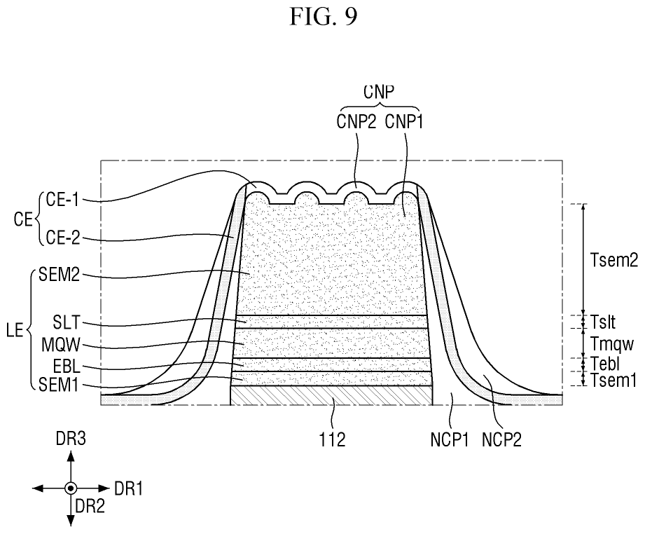

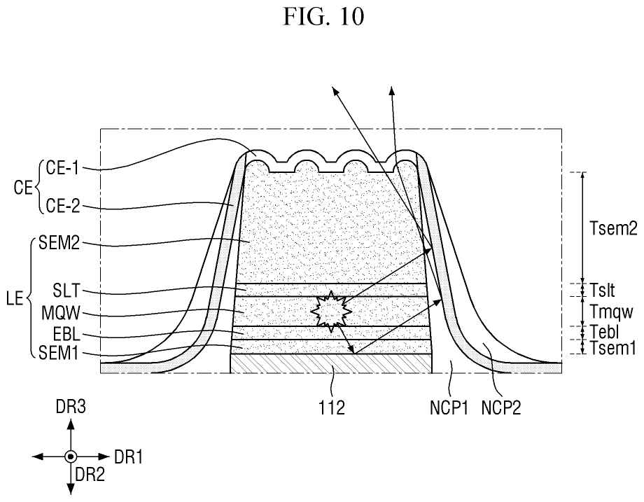

FIG. 8 is a schematic cross-sectional view of a display panel taken along B-B′ of FIG. 2 according to an embodiment. FIG. 9 is a schematic enlarged cross-sectional view of the light emitting element of FIG. 8 according to an embodiment. FIG. 10 is a schematic enlarged cross-sectional view of the light emitting element of FIG. 8 illustrating a traveling direction of light in a light emitting element according to an embodiment.

The display panel 100 illustrated with reference to FIGS. 8 to 10 differs from the display panel 100 of FIGS. 4 to 6 only in that the upper surface of the light emitting element LE and the second portion CE-2 of the common electrode CE disposed on the upper surface of the light emitting element LE have a concavo-convex pattern CNP. Therefore, the description will focus on the differences.

The upper surface of the light emitting element LE may have a first concavo-convex pattern CNP1, and the second portion CE-2 of the common electrode CE disposed on the upper surface of the light emitting element LE may have a second concave-convex pattern CNP2. Since the upper surface of the light emitting element LE is the second semiconductor layer SEM2, the upper surface of the second semiconductor layer SEM2 may have the first concavo-convex pattern CNP1. The concavo-convex pattern of the second semiconductor layer SEM2 may be formed by growing on a patterned sapphire substrate (PSS). The second concavo-convex pattern CNP2 and the first concavo-convex pattern CNP1 may have a same shape. For convenience of description, the first concavo-convex pattern CNP1 and the second concavo-convex pattern CNP2 are referred to as concavo-convex patterns CNP.

Each of the concavo-convex patterns NCP may have a convex portion and a concave portion as a whole. The cross-sectional shape of the concavo-convex pattern NCP may be hemispherical or triangular, but the disclosure is not limited thereto.

In the thickness direction, the concave portions of the first concave-convex pattern CNP1 may be disposed to correspond to the concave portions of the second concave-convex pattern CNP2, and the convex portions of the first concave-convex pattern CNP1 may be disposed to correspond to the convex portions of the second concave-convex pattern CNP2.

Referring to FIG. 10, the light emitted from the active layer MQW to the side of the light emitting element LE may be reflected by the second portion CE-2 of the common electrode CE and proceed to the upper surface of the light emitting element LE. The light proceeding to the upper surface of the light emitting element LE may pass through the first portion CE-1 with little loss.

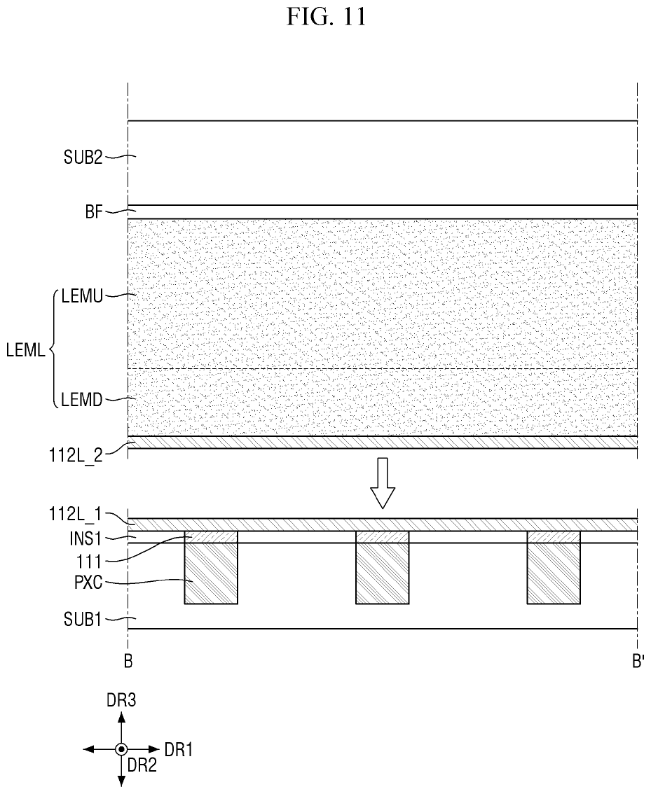

FIGS. 11 to 19 are schematic cross-sectional views illustrating a method of manufacturing a display device according to an embodiment. FIGS. 11 to 19 are schematic cross-sectional views illustrating a manufacturing method of the display device according to an embodiment and correspond to the cross-sectional views of the display panel shown in FIG. 4.

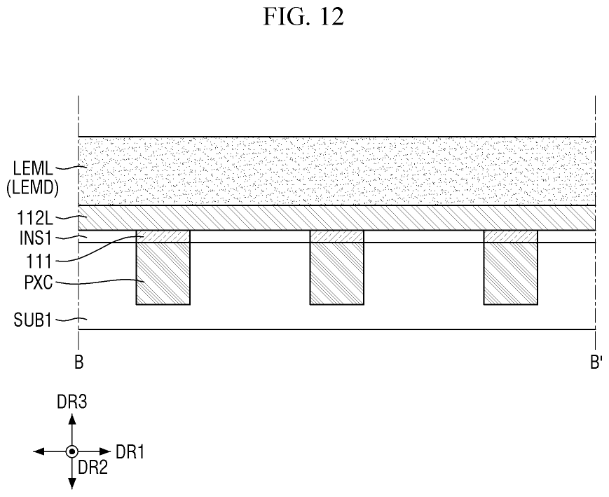

As shown in FIGS. 11 and 12, a first connection electrode layer 112L_1 may be formed on the pixel electrodes 111 of the first substrate SUB1 and the planarization insulating layer INS1, and a second connection electrode layer 112L_2 may be formed on a light emitting material layer LEML of the second substrate SUB2.

For example, the planarization insulating layer INS1 may be formed on the first substrate SUB1 on which the pixel electrodes 111 are not disposed. The upper surface of the planarization insulating layer INS1 and the upper surface of each of the pixel electrodes 111 may be connected flatly (e.g., coplanar with each other). For example, a height difference between the upper surface of the first substrate SUB1 and the upper surface of the pixel electrode 111 may be eliminated by the planarization insulating layer INS1. The planarization insulating layer INS1 may be formed of an inorganic material such as silicon oxide (SiO₂), aluminum oxide (Al₂O₃), or hafnium oxide (HfOₓ).

The first connection electrode layer 112L_1 may be deposited on the pixel electrodes 111 and the planarization insulating layer INS1. The first connection electrode layer 112L_1 may include gold (Au), copper (Cu), aluminum (Al), or tin (Sn).

A buffer film BF may be formed on a surface of the second substrate SUB2. The second substrate SUB2 may be a silicon substrate or a sapphire substrate. The buffer layer BF may be formed of an inorganic layer such as a silicon oxide layer (SiO₂), an aluminum oxide layer (Al₂O₃), or a hafnium oxide layer (HfOₓ).

The light emitting material layer LEML may be disposed on the buffer layer BF. The light emitting material layer LEML may include a first semiconductor material layer LEMD and a second semiconductor material layer LEMU. The second semiconductor material layer LEMU may be disposed on the buffer layer BF, and the first semiconductor material layer LEMD may be disposed on the second semiconductor material layer LEMU. A thickness of the second semiconductor material layer LEMU may be greater than a thickness of the first semiconductor material layer LEMD.

As shown in FIG. 5, the first semiconductor material layer LEMD may include the first semiconductor layer SEM1, the electron blocking layer EBL, the active layer MQW, the superlattice layer SLT, and the second semiconductor layer SEM2. The second semiconductor material layer LEMU may be a semiconductor layer not doped with a dopant, for example, an undoped semiconductor layer. For example, the second semiconductor material layer LEMU may be undoped-GaN not doped with a dopant.

The second connection electrode layer 112L_2 may be deposited on the first semiconductor material layer LEMD. The second connection electrode layer 112L_2 may include gold (Au), copper (Cu), aluminum (Al), or tin (Sn).

Thereafter, the first connection electrode layer 112L_1 and the second connection electrode layer 112L_2 may be bonded, and the second substrate SUB2 may be removed.

The first connection electrode layer 112L_1 of the first substrate SUB1 and the second connection electrode layer 112L_2 of the second substrate SUB2 may be brought into contact. A connection electrode layer 112L may be formed by melting and bonding the first connection electrode layer 112L_1 and the second connection electrode layer 112L_2 at a temperature (e.g., a predetermined temperature). For example, the connection electrode layer 112L may be disposed between the pixel electrodes 111 of the first substrate SUB1 and the light emitting material layer LEML of the second substrate SUB2 and serves as a bonding metal layer to bond the pixel electrodes 111 of the first substrate SUB1 and the light emitting material layer LEML of the second substrate SUB2.

The second substrate SUB2 and the buffer layer BF may be removed through a polishing process such as a chemical mechanical polishing (CMP) process and/or an etching process. Also, the second semiconductor material layer LEMU of the light emitting material layer LEML may be removed through a polishing process such as a CMP process.

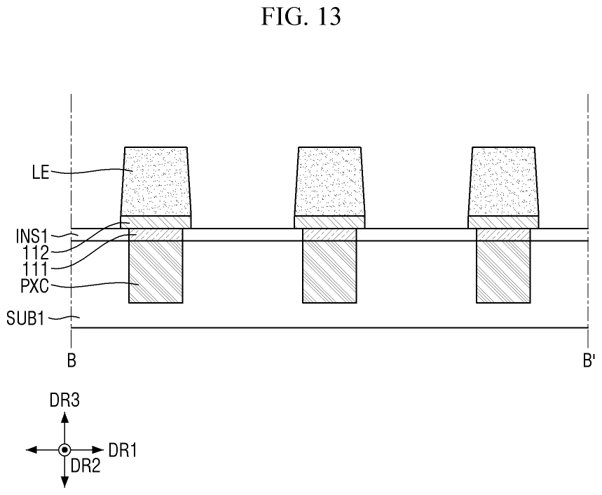

Referring to FIG. 13, the light emitting elements LE may be formed by etching the light emitting material layer LEML and the connection electrode layer 112L.

To this end, a mask pattern (not shown) may be formed on the light emitting material layer LEML.

The mask pattern may be formed on the upper surface of the light emitting material layer LEML. The upper surface of the light emitting material layer LEML may be the upper surface of the first light emitting material layer LEMD exposed by removing the second substrate SUB2, the buffer film BF, and the second light emitting material layer LEMU. The mask pattern MP may be disposed in an area where the light emitting element LE is to be formed. The mask pattern MP may overlap the pixel electrode 111 in the third direction DR3. A thickness of the mask pattern MP may be in a range of approximately 0.01 to approximately 1 μm.

The light emitting elements LE may be formed by etching the light emitting material layer LEML and the connection electrode layer 112L according to the mask pattern MP, and the mask pattern MP may be removed.

The mask pattern MP may not be etched by a first etching material for etching the light emitting material layer LEML and a second etching material for etching the connection electrode layer 112L. As a result, the light emitting material layer LEML and the connection electrode layer 112L in the area where the mask pattern MP is disposed may not be etched. Therefore, the connection electrode 112 and the light emitting element LE may be formed on the upper surface of each of the pixel electrodes 111. The mask pattern MP is removed.

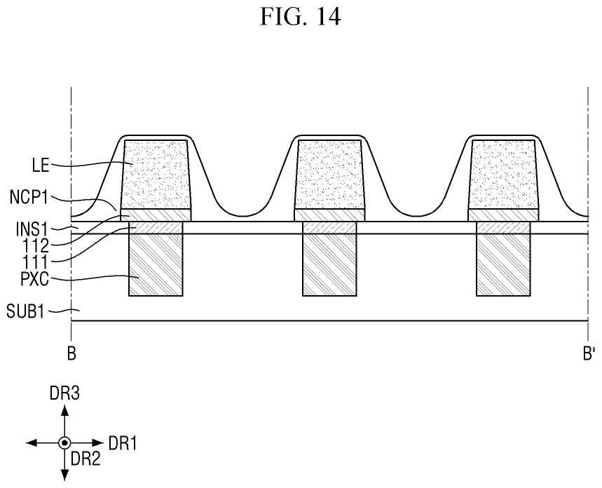

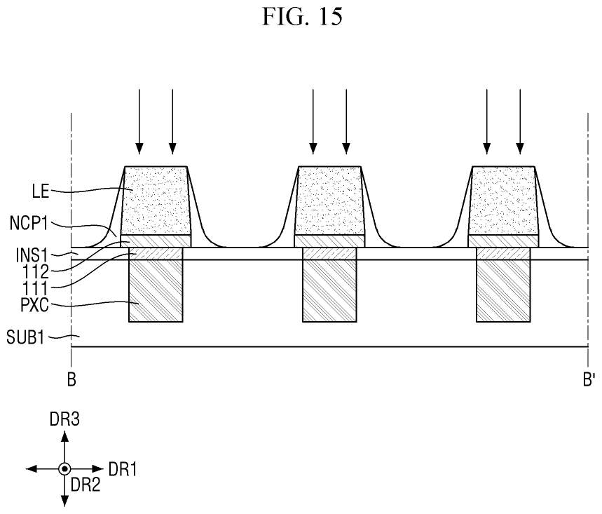

Referring to FIGS. 14 and 15, the step coverage prevention layer NCP1 may be formed on the side surface of the light emitting element LE. The step coverage prevention layer NCP1 may have a sloper structure having a curvature. The step coverage prevention layer NCP1 may be convexly shaped with the light emitting element LE.

As shown in FIG. 14, a material for preventing step coverage may be deposited on the entire surface of the substrate to cover the light emitting element LE. The material for preventing step coverage may include, for example, one of an inorganic material, an organic material, and an organic-inorganic hybrid material. The inorganic material may include, for example, silicon oxide (SiO₂), aluminum oxide (Al₂O₃), or hafnium oxide (HfOₓ). The organic material may include an epoxy-based resin, an acrylic-based resin, a cardo-based resin, or an imide-based resin. The organic-inorganic hybrid material may be a material that has the properties of organic materials and inorganic materials by physically or chemically combining organic and inorganic materials.

A large voltage difference may be formed in the third direction DR3 without a separate mask, and a material for preventing step coverage may be etched by an etching material. The etching material may move in the third direction DR3 by voltage control, for example, from the top to the bottom, and the material for preventing step coverage may be etched to form the step coverage prevention layer NCP1. As a result, the material for preventing step coverage disposed on the horizontal plane defined by the first and second directions DR1 and DR2 may be quickly removed, whereas the material for preventing step coverage disposed on the vertical plane defined by the third direction DR3 may be slowly removed. Therefore, the etching may be continued until all the materials for preventing step coverage on the light emitting element LE are removed. The etching may be stopped in case that all the materials for preventing step coverage on the light emitting element LE are removed. Accordingly, the step coverage prevention layer NCP1 having a sloper structure having a curvature may be formed on the side surface of the light emitting element LE. The step coverage prevention layer NCP1 may not overlap the light emitting element LE in the third direction DR3.

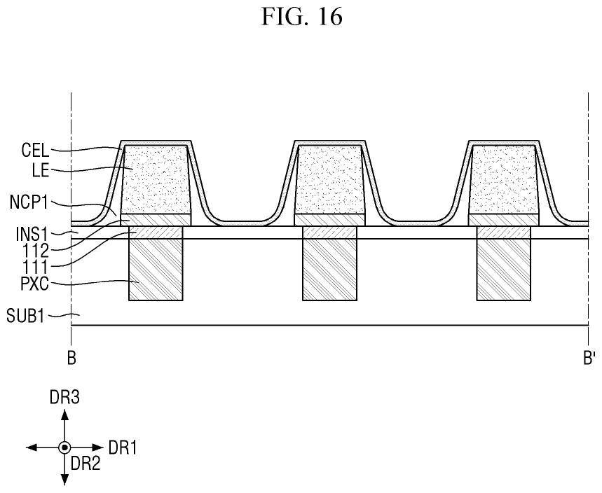

Referring to FIGS. 16 to 19, the common electrode CE may be formed on the upper surface of the light emitting element LE and the upper surface of the step coverage prevention layer NCP1, and the common electrode CE formed on the upper surface of the light emitting element LE may be formed of an oxide of a material forming the common electrode CE formed on the upper surface of the step coverage prevention layer NCP1.

For example, the common electrode material layer CEL may be deposited on the upper surface of the light emitting element LE and the upper surface of the step coverage prevention layer NCP1.

For example, the common electrode material layer CEL may be deposited on the upper surface of the light emitting element LE and the upper surface of the step coverage prevention layer NCP1 by a method such as sputtering.

The common electrode material layer CEL may include InSn or InZn.

For example, the common electrode material layer CEL may include In:Sn=90:10 wt %. In another example, the common electrode material layer CEL may include In:Zn=90:10 wt %.

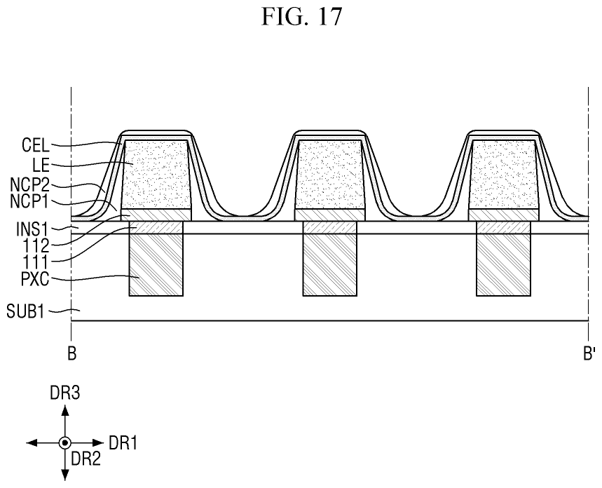

Subsequently, referring to FIG. 17, a material for preventing oxidation may be deposited over the entire substrate SUB1 to cover the entire common electrode material layer CEL. The material for preventing oxidation may include, for example, one of an inorganic material, an organic material, and an organic-inorganic hybrid material. The inorganic material may include, for example, silicon oxide (SiO₂), aluminum oxide (Al₂O₃), or hafnium oxide (HfOₓ). The organic material may include an epoxy-based resin, an acrylic-based resin, a cardo-based resin, or an imide-based resin. The organic-inorganic hybrid material may be a material that has the properties of organic materials and inorganic materials by physically or chemically combining organic and inorganic materials.

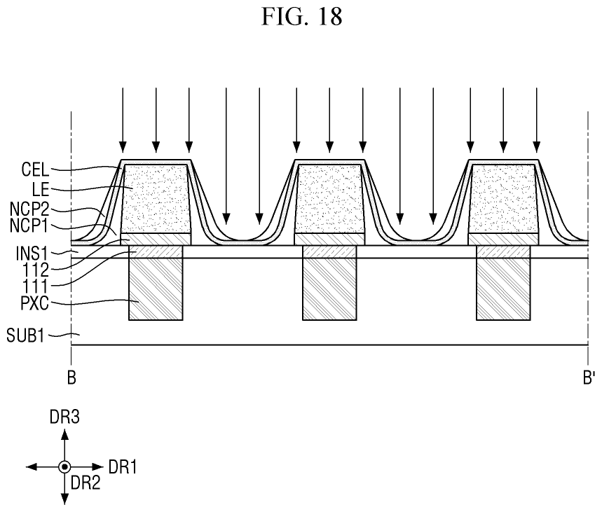

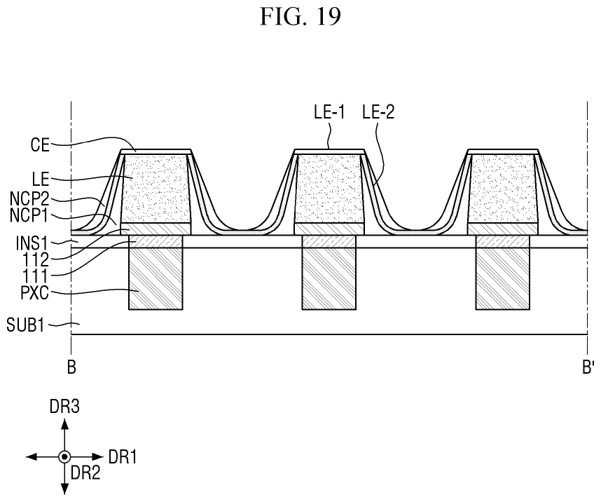

As shown in FIG. 18, a large voltage difference may be formed in the third direction DR3 without a separate mask, and the material for preventing oxidation may be etched by an etching material. The oxidation prevention layer NCP2 may be formed by etching the material for preventing oxidation while moving in the third direction DR3 by voltage control, for example, moving from top to the bottom. Due to this, the material for preventing oxidation disposed on the horizontal plane defined by the first and second directions DR1 and DR2 may be quickly removed, whereas the material for preventing oxidation disposed on the vertical plane defined by the third direction DR3 may be removed slowly. Therefore, the etching may continue until all the materials for preventing oxidation disposed on the light emitting element LE are removed. The etching may stop in case that all the materials for preventing step coverage on the light emitting element LE are removed. As a result, the oxidation prevention layer NCP2 having a sloper structure having a curvature may be formed on the side of the light emitting element LE. The oxidation prevention layer NCP2 may prevent oxidation of the common electrode CE protected by the oxidation prevention layer NCP2 in an oxidation process to be described below with reference to FIG. 19.

Referring to FIG. 19, an oxygen plasma treatment may be performed while the common electrode CE on the light emitting element LE is exposed. The exposed common electrode CE on the light emitting element LE may be readily oxidized. On the other hand, the common electrode CE disposed on the side of the light emitting element LE that does not overlap the light emitting element LE surrounded by the oxidation prevention layer NCP2 may be prevented from being oxidized. Therefore, the common electrode CE on the light emitting element LE may become InSnOₓ, which is an oxide of InSn of the common electrode CE that does not overlap the light emitting element LE in the third direction DR3.

InSnOₓ may have higher transparency and lower reflectivity than InSn.

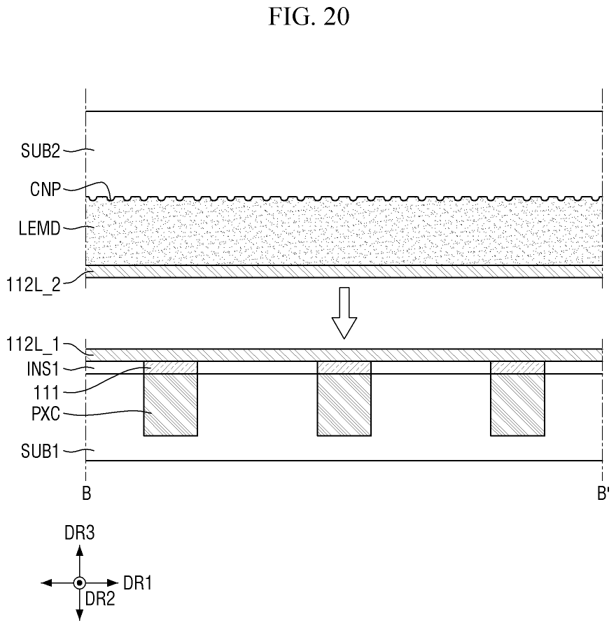

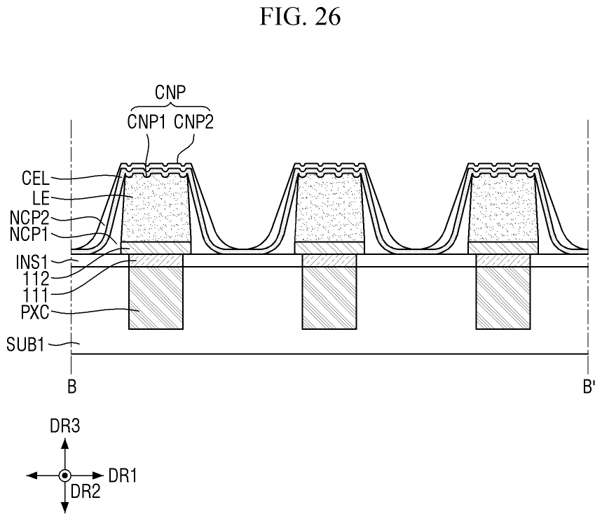

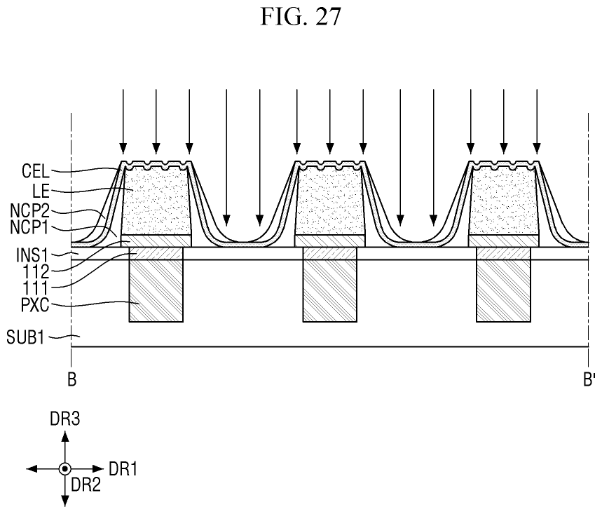

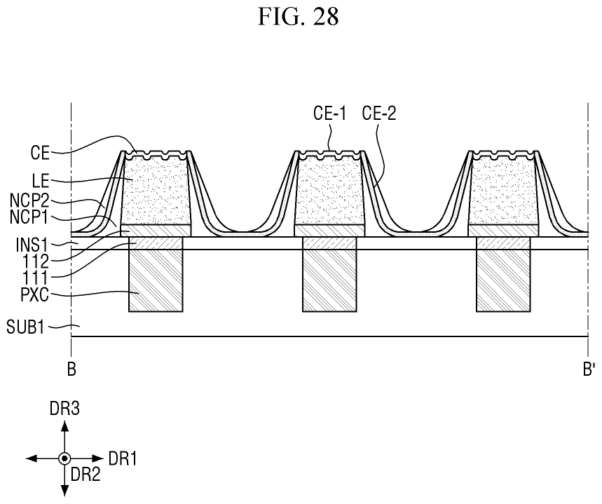

FIGS. 20 to 28 are schematic cross-sectional views illustrating a method of manufacturing a display device according to another embodiment. FIGS. 20 to 28 are schematic cross-sectional views illustrating a method of manufacturing a display device according to an embodiment, corresponding to cross-sectional views of the display panel shown in FIG. 8.

The manufacturing method of the display device according to another embodiment described with reference to FIGS. 20 to 28 differs from the manufacturing method of the display device described with reference to FIGS. 11 to 19 in that the second substrate is the patterned sapphire substrate (PSS) substrate. Therefore, the description will focus on the differences.

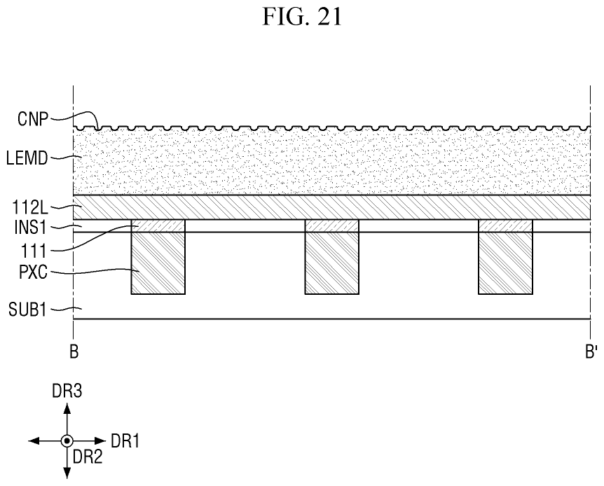

As shown in FIGS. 20 and 21, the first connection electrode layer 112L_1 may be formed on the pixel electrodes 111 of the first substrate SUB1 and the planarization insulating layer INS1, and the second connection electrode layer 112L_2 may be formed on the first semiconductor material layer LEMD of the second substrate SUB2.

For example, the planarization insulating layer INS1 may be formed on the first substrate SUB1 on which the pixel electrodes 111 are not disposed. The upper surface of the planarization insulating layer INS1 and the upper surface of each of the pixel electrodes 111 may be connected flatly (e.g., coplanar with each other). For example, the height difference between the upper surface of the first substrate SUB1 and the upper surface of the pixel electrode 111 may be eliminated by the planarization insulating layer INS1. The planarization insulating layer INS1 may be formed of an inorganic material such as silicon oxide (SiO₂), aluminum oxide (Al₂O₃), or hafnium oxide (HfOₓ).

The first connection electrode layer 112L_1 may be deposited on the pixel electrodes 111 and the planarization insulating layer INS1. The first connection electrode layer 112L_1 may include gold (Au), copper (Cu), aluminum (Al), or tin (Sn).

The second substrate SUB2 may be a patterned sapphire substrate (PSS) substrate.

The second substrate SUB2 may be a silicon substrate or a sapphire substrate. The second substrate SUB2 may be a patterned sapphire substrate (PSS) substrate.

The second substrate SUB2 may have a concavo-convex pattern CVP. The cross section of the concavo-convex pattern CVP may be circular, and the overall shape of the concavo-convex pattern CVP may be circular, hemispherical, or conical. As such, the concave-convex pattern CVP of the PSS substrate may be formed on the upper surface of the substrate in a bilaterally symmetrical or omnidirectionally symmetrical form with respect to the center of the pattern and increases the light extraction efficiency by reflecting light incident in a certain angular range.

However, the width of the upper surface of the second substrate SUB2 exposed between the adjacent concavo-convex patterns CVP may vary from location to location, and a distance between adjacent concavo-convex patterns CVP may vary according to positions.

The semiconductor material layer LEMD may be formed on the second substrate SUB2. As shown in FIG. 9, the semiconductor material layer LEMD may include the first semiconductor layer SEM1, the electron blocking layer EBL, the active layer MQW, the superlattice layer SLT, and the second semiconductor layer SEM2. The second semiconductor layer SEM2 may include a concavo-convex pattern CNP corresponding to the concavo-convex pattern CVP of the second substrate SUB2.

The second connection electrode layer 112L_2 may be deposited on the first semiconductor material layer LEMD. The second connection electrode layer 112L_2 may include gold (Au), copper (Cu), aluminum (Al), or tin (Sn).

Thereafter, the first connection electrode layer 112L_1 and the second connection electrode layer 112L_2 may be bonded, and the second substrate SUB2 may be removed.

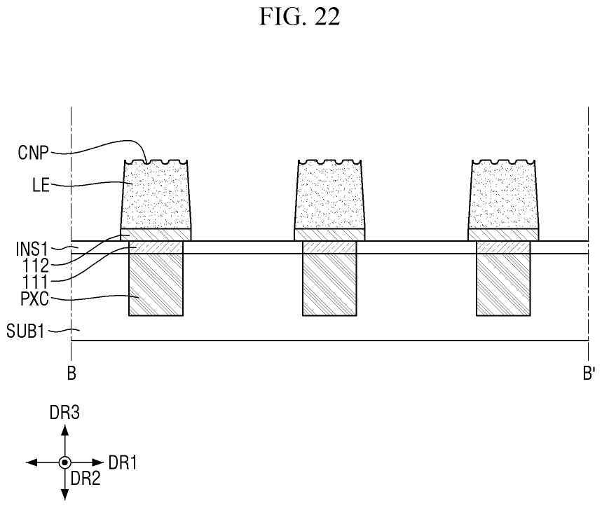

Referring to FIG. 22, the light emitting elements LE may be formed by etching the first semiconductor material layer LEMD and the connection electrode layer 112L. Since the etching of the first semiconductor material layer LEMD and the connection electrode layer 112L has been described with reference to FIG. 13, overlapping descriptions will be omitted. However, it is different from the light emitting element LE described with reference to FIG. 13 in that the upper surface of the formed light emitting element LE has the concavo-convex pattern CNP.

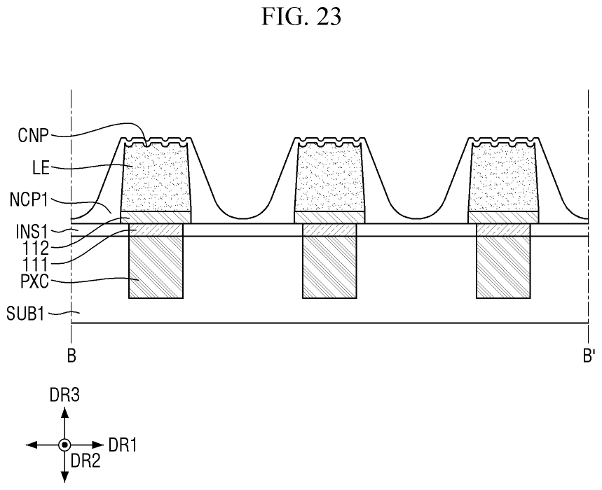

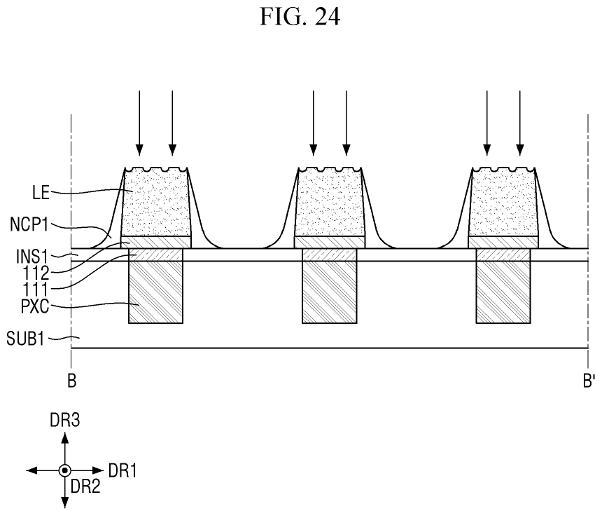

As shown in FIGS. 23 and 24, the step coverage prevention layer NCP1 may be formed on the side surface of the light emitting element LE. Since the method of forming the step coverage prevention layer NCP1 has been described with reference to FIGS. 14 and 15, a detailed description thereof will be omitted.

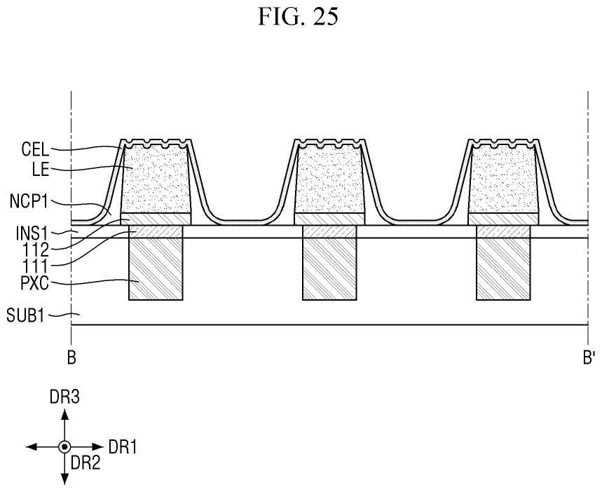

Referring to FIGS. 25 to 28, the common electrode CE may be formed on the upper surface of the light emitting element LE and the upper surface of the step coverage prevention layer NCP1, but the common electrode CE formed on the upper surface of the light emitting element LE may be formed of an oxide of the material forming the common electrode CE formed on the upper surface of the step coverage prevention layer NCP1. Since the method of forming the common electrode CE has been described with reference to FIGS. 16 to 19, a detailed description thereof will be omitted. However, it differs from FIGS. 16 to 19 in that the upper surface of the common electrode CE has the concavo-convex pattern.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate having a pixel electrode;
a light emitting element disposed on the pixel electrode and including a first semiconductor layer, an active layer, and a second semiconductor layer;
a step coverage prevention layer surrounding the light emitting element in a plan view;
a common electrode disposed on the light emitting element and the step coverage prevention layer; and
an oxidation prevention layer disposed on a portion of the common electrode that does not overlap the light emitting element in a thickness direction, wherein
the common electrode includes a first portion disposed on the light emitting element and a second portion disposed between the oxidation prevention layer and the step coverage prevention layer, and
a material forming the first portion is an oxide of a material forming the second portion.

2. The display device of claim 1, wherein
the first portion includes InSnOₓ and the second portion includes InSn, or
the first portion includes InZnOₓ and the second portion includes InZn.

3. The display device of claim 2, wherein the second portion extends from the first portion and surrounds a side surface of the light emitting element.

4. The display device of claim 3, wherein the second portion has a sloper structure having a curvature.

5. The display device of claim 4, wherein
the oxidation prevention layer has the sloper structure having the curvature, and
the step coverage prevention layer has the sloper structure having the curvature.

6. The display device of claim 4, wherein the second portion, the oxidation prevention layer, and the step coverage prevention layer have a convex shape on a side surface of the light emitting element.

7. The display device of claim 4, wherein
an upper surface of the second portion is in contact with the oxidation prevention layer, and
a bottom surface of the second portion is in contact with the step coverage prevention layer.

8. The display device of claim 2, wherein an amount of In is the second portion is about 90 wt %.

9. The display device of claim 2, wherein an upper surface of the second semiconductor layer and the first portion have a concavo-convex pattern.

10. The display device of claim 2, wherein the oxidation prevention layer and the step coverage prevention layer include an insulating material including one of an organic material, an inorganic material, and an organic-inorganic hybrid material.

11. A method of manufacturing a display device comprising:
bonding a first substrate and a second substrate by melting bonding a connection electrode layer disposed between the first substrate having a pixel electrode and the second substrate having a semiconductor material layer;
forming a plurality of light emitting elements by removing the second substrate and etching the semiconductor material layer;
forming a step coverage prevention layer surrounding the plurality of light emitting elements in a plan view;
depositing a common electrode material layer on the plurality of light emitting elements and the step coverage prevention layer;
forming an oxidation prevention layer on a portion of the common electrode material layer that does not overlap the plurality of light emitting elements in a thickness direction; and
forming a common electrode by oxidizing a portion of the common electrode material layer disposed on the plurality of light emitting elements.

12. The method of claim 11, wherein the common electrode material layer includes In:Sn=90:10 Wt % or In:Zn=90:10 Wt %.

13. The method of claim 12, wherein the forming of the step coverage prevention layer includes:
spreading a material for preventing step coverage on an entire area of the first substrate on which the plurality of light emitting elements is disposed;
covering the plurality of light emitting elements with the material for preventing step coverage; and
etching the material for preventing step coverage disposed on an upper surface of the plurality of light emitting elements to expose the upper surface of the plurality of light emitting elements after forming a sloper structure having a convex curvature to a side of the plurality of light emitting elements.

14. The method of claim 13, wherein the forming of the oxidation prevention layer includes:
spreading a material for preventing oxidation on the entire area of the first substrate on which the common electrode material layer is deposited;
covering the plurality of light emitting elements with the material for preventing oxidation; and
etching the material for preventing oxidation disposed on the upper surface of the plurality of light emitting elements to expose the upper surface of the plurality of light emitting elements after forming a sloper structure having a convex curvature to the side of the plurality of light emitting elements.

15. The method of claim 14, wherein the oxidation prevention layer and the step coverage prevention layer include an insulating material including one of an organic material, an inorganic material, and an organic-inorganic hybrid material.

16. The method of claim 14, wherein the forming of the common electrode includes oxidizing the common electrode material layer disposed on the upper surface of the plurality of light emitting elements by oxygen plasma treatment.

17. The method of claim 11, wherein
the plurality of light emitting elements include a first semiconductor layer, an active layer, and a second semiconductor layer sequentially stacked, and
the common electrode is in contact with an upper surface of the second semiconductor layer.

18. The method of claim 17, wherein the second substrate is a patterned sapphire substrate (PSS) having a concave-convex pattern.

19. The method of claim 18, wherein the upper surface of the second semiconductor layer has the concavo-convex pattern.

20. The method of claim 19, wherein a portion of the common electrode formed on an upper surface of the plurality of light emitting elements has the concave-convex pattern.
